(19) United States
(12) Patent Application Publication
(10) Pub. No.: US 2022/0270821 A1
(43) Pub. Date: Aug. 25, 2022

(54) SUPERCAPACITOR CARRIER AND SERVER

(71) Applicants: Inventec (Pudong) Technology Corporation, Shanghai (CN); INVENTEC CORPORATION, Taipei (TW)

(72) Inventors: Shuai Zhang, Shanghai (CN); Xiaogang Lu, Shanghai (CN)

(21) Appl. No.: 17/348,896

(22) Filed: Jun. 16, 2021

(30) Foreign Application Priority Data
Feb. 20, 2021 (CN) 202110194517.9

(51) Int. Cl. H01G 2/04; H01G 11/78

(52) U.S. Cl. CPC H01G 2/04; H01G 11/78

(57) ABSTRACT

This disclosure relates to a supercapacitor carrier configured to accommodate a supercapacitor and to be connected to a connector. The supercapacitor carrier includes a support component, a holder, and a baffle. The support component includes a substrate part and an insertion part. The substrate part is connected to the insertion part. The insertion part is configured to be inserted into the connector. The holder includes a main plate and a first side plate that are spaced apart from each other and form an accommodation space therebetween. The accommodation space is configured to accommodate the supercapacitor. The first side plate is connected to the main plate, and the first side plate is disposed on the substrate part. The baffle is disposed on the substrate part. The baffle and the insertion part are located at different sides of the substrate part.

### CROSS-REFERENCE TO RELATED APPLICATIONS

This non-provisional application claims priority under 35 U.S.C. § 119(a) on Patent Application No(s). 202110194517.9 filed in China, P.R.C. on Feb. 20, 2021, the entire contents of which are hereby incorporated by reference.

### BACKGROUND OF THE INVENTION

### Technical Field of the Invention

The present disclosure relates to a supercapacitor carrier and a server, more particularly to a supercapacitor carrier applicable to a server.

### Description of the Related Art

A server usually accommodates a large number of hard disks for storing a large amount of data. The hard disks generally cooperate with a supercapacitor in order to prevent data loss due to unexpected situation such as power failure.

The conventional servers so far do not have a fixed specification for the installation of the supercapacitor, thus it always needs to find an extra space for the supercapacitor. And for the supercapacitor to fit different servers, a customized carrier is needed; that is, the typical supercapacitor carriers are exclusive only for specific servers. Thus, it is desirable to have a carrier applicable to all kinds of supercapacitors.

### SUMMARY OF THE INVENTION

The present disclosure provides a supercapacitor carrier and a server capable to provide a fixed specification for the installation of the supercapacitor.

According to one aspect of the present disclosure, a supercapacitor carrier configured to accommodate a supercapacitor and to be connected to a connector. The supercapacitor carrier includes a support component, a holder, and a baffle. The support component includes a substrate part and an insertion part. The substrate part is connected to the insertion part. The insertion part is configured to be inserted into the connector. The holder includes a main plate and a first side plate. The main plate and the substrate part are spaced apart from each other and form an accommodation space therebetween. The accommodation space is configured to accommodate the supercapacitor. The first side plate is connected to the main plate, and the first side plate is disposed on the substrate part. The baffle is disposed on the substrate part. The baffle and the insertion part are located at different sides of the substrate part.

According to another aspect of the present disclosure, a server includes a chassis, a circuit board, a supercapacitor carrier, and a supercapacitor. The circuit board is disposed on the chassis, and the circuit board has a connector. The supercapacitor carrier includes a support component, a holder, and a baffle. The support component includes a substrate part and an insertion part. The substrate part is connected to the insertion part. The insertion part is inserted into the connector. The holder includes a main plate and a first side plate. The main plate and the substrate part are spaced apart from each other and form an accommodation space therebetween. The first side plate is connected to the main plate, and the first side plate is disposed on the substrate part. The baffle is disposed on the substrate part and the chassis. The baffle and the insertion part are located at different sides of the substrate part. The supercapacitor is disposed in the accommodation space.

According to the supercapacitor carrier and the server discussed above, the supercapacitor carrier that can accommodate the supercapacitor can be installed to any one of idle connectors of the server, thus there is no need to additionally arrange a space from the server for the supercapacitor. In other words, since the insertion part is universal for the connector standard, the supercapacitor carrier is ensured to fit different types of servers. In addition, the first side plates of the holder are able to secure the position of the supercapacitor in the accommodation space.

### BRIEF DESCRIPTION OF THE DRAWINGS

The present disclosure will become more fully understood from the detailed description given hereinbelow and the accompanying drawings which are given by way of illustration only and thus are not intending to limit the present disclosure and wherein:

FIG. 1 is a perspective view of a server according to one embodiment of the present disclosure;

FIG. 2 is a perspective view of a supercapacitor carrier of the server in FIG. 1 and a supercapacitor; and

FIG. 3 is an exploded view of the supercapacitor carrier and the supercapacitor in FIG. 2.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

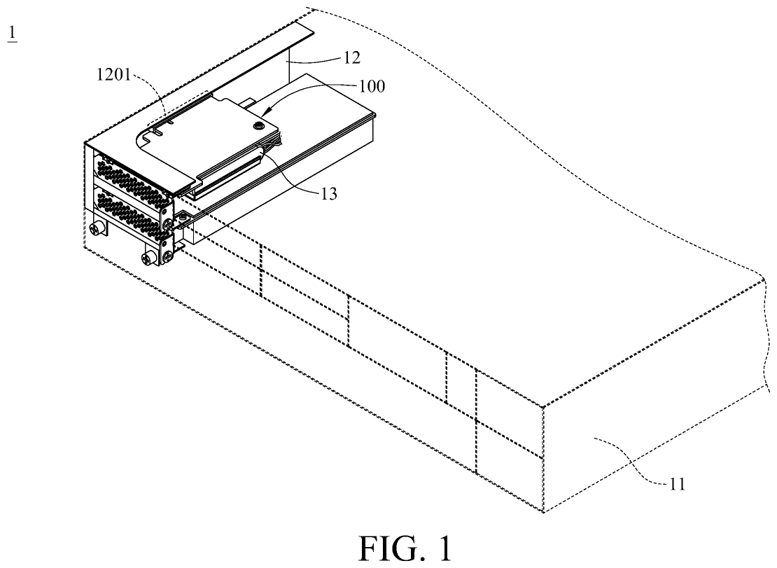

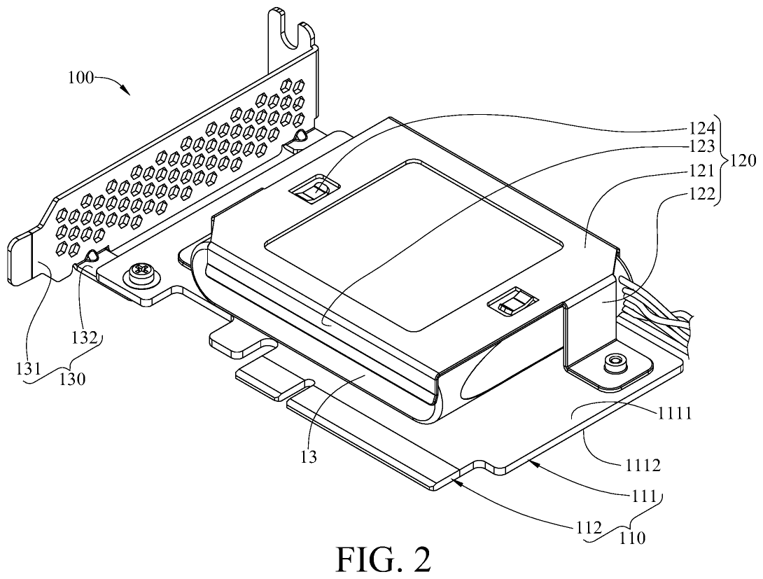

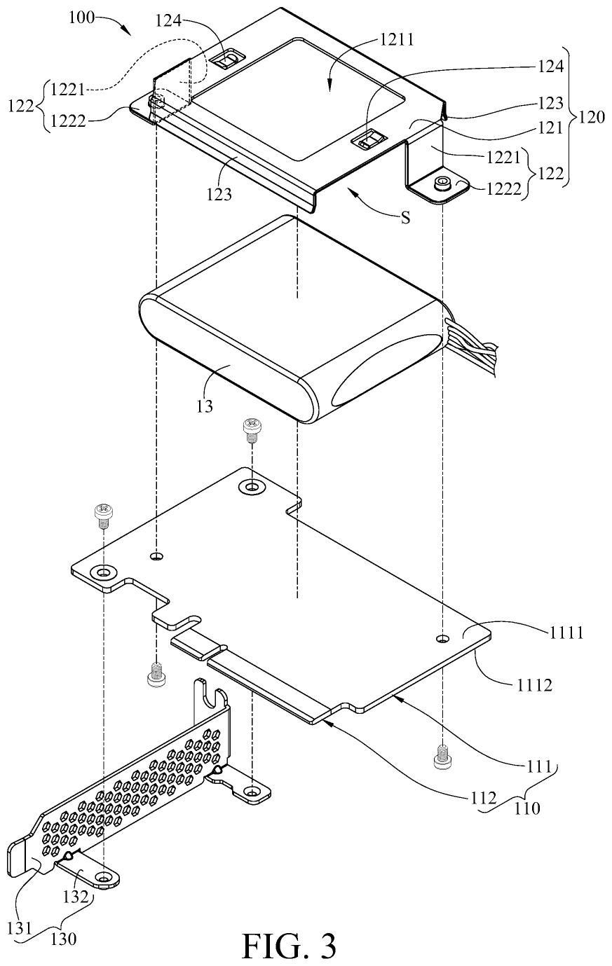

Please refer to FIG. 1 to FIG. 3, where FIG. 1 is a perspective view of a server 1 according to one embodiment of the present disclosure, FIG. 2 is a perspective view of a supercapacitor carrier 100 of the server 1 in FIG. 1 and a supercapacitor 13, and FIG. 3 is an exploded view of the supercapacitor carrier 100 and the supercapacitor 13 in FIG. 2.

In this embodiment, the server 1 includes a chassis 11, a circuit board 12, the supercapacitor carrier 100, and a supercapacitor 13. The circuit board 12 is disposed on the chassis 11, and the circuit board 12 has a connector 1201. The connector 1201 may be a female connector that complies with the PCI-e (peripheral component interconnect express) standard. The supercapacitor carrier 100 is connected to the connector 1201 of the circuit board 12. The supercapacitor 13 (can also be called “electrostatic double-layer capacitor” or “ultracapacitor”), uses electrostatic double-layer capacitance and electrochemical pseudocapacitance. The supercapacitor 13 is an electrochemical capacitor with a capacity that is at least 10 to 1000 times more than that of typical electrolytic capacitors. The supercapacitor 13 is accommodated in the supercapacitor carrier 100.

In detail, the supercapacitor carrier 100 includes a support component 110, a holder 120, and a baffle 130. The support component 110 includes a substrate part 111 and an insertion part 112. The substrate part 111 is connected to the insertion part 112, and the substrate part 111 has a first surface 1111 and a second surface 1112 that are opposite to each other. The insertion part 112 may have the same shape as a male connector that complies with the PCI-e standard and suitable for being inserted into the connector 1201. In this and some embodiments of the present disclosure, the supercapacitor 13 may be electrically connected to the circuit board 12 via another circuit path (not numbered) instead of the insertion part 112 and the connector 1201; in such a case, the insertion part 112 may omit terminals thereon and remain in the shape suitable for being inserted into the connector 1201 to secure the position of the supercapacitor 13 with respect to the circuit board 12. However, the present disclosure is not limited thereto. In some other embodiments, the supercapacitor may be electrically connected to the circuit board via the connection of the insertion part and the connector.

In this embodiment, the holder 120 includes a main plate 121 and two first side plates 122. The main plate 121 and the substrate part 111 are spaced apart from each other and form an accommodation space S therebetween. The accommodation space S is for accommodating the supercapacitor 13. The first side plates 122 are connected to two opposite sides of the main plate 121. The first side plates 122 are disposed on the substrate part 111 via fasteners, such as screws.

As shown in FIG. 3, in this and some embodiments of the present disclosure, each first side plate 122 includes a first blocking part 1221 and a first mount part 1222. The first blocking parts 1221 are connected to and located between the main plate 121 and the first mount parts 1222. The first mount parts 1222 are attached to and fixed to the first surface 1111 of the substrate part 111 via, for example, screws.

In this and some embodiments of the present disclosure, the holder 120 may further include two second side plates 123. The second side plates 123 are connected to another two opposite sides of the main plate 121 and located between the first side plates 122. In detail, as shown in FIG. 3, the first side plates 122 and the second side plates 123 are alternatively located at different sides of the main plate 121. The second side plates 123 extend toward the substrate part 111, and the second side plates 123 have curved shapes that are convex toward the accommodation space S.

In this embodiment, the baffle 130 is disposed on the substrate part 111. In this and some embodiments of the present disclosure, the baffle 130 includes a second blocking part 131 and a second mount part 132. The second blocking part 131 is located at a side of the substrate part 111. The second blocking part 131 is disposed on the chassis 11 via, for example, screws. The second blocking part 131 is able to prevent dust from entering the chassis 11. The second mount part 132 is connected to the second blocking part 131, and the second mount part 132 is attached to and fixed to the second surface 1112 of the substrate part 111 via, for example, screws. In this embodiment, the baffle 130 and the insertion part 112 are located at different sides of the substrate part 111, and the baffle 130 does not physically interfere with the insertion of the insertion part 112 into the connector 1201.

In this embodiment, the supercapacitor carrier 100 that can accommodate the supercapacitor 13 can be installed to any one of idle connectors (i.e., the connector 1201) of the server 1, thus there is no need to additionally arrange a space from the server 1 for the supercapacitor 13. In other words, since the insertion part 112 is universal for the connector standard, the supercapacitor carrier 100 is ensured to fit different types of servers.

In addition, the first side plates 122 of the holder 120 are able to secure the position of the supercapacitor 13 in the accommodation space S. Further, in this and some embodiments of the present disclosure, the first side plates 122 and the second side plates 123 surround the supercapacitor 13 so that the supercapacitor 13 is prevented from moving in all directions when being held in the holder 120. And, the second side plates 123 of curved shapes are able to press against the supercapacitor 13 so as to eliminate the assembly tolerance between the supercapacitor 13 and the second side plates 123 and further secure the position of the supercapacitor 13 in the accommodation space S.

In this and some embodiments of the present disclosure, the holder 120 may further include two elastic parts 124. The elastic parts 124 are elastically flexible and are connected to the main plate 121. The elastic parts 124 extend toward the substrate part 111 and each have a free end used to press against the supercapacitor 13, stabling the position of the supercapacitor 13 in the accommodation space S.

In this and some embodiments of the present disclosure, the main plate 121 of the holder 120 may have an opening 1211. The opening 1211 is connected to the accommodation space S so that it exposes a side of the supercapacitor 13 and can be served as a path for heat dissipation.

According to the supercapacitor carrier and the server discussed above, the supercapacitor carrier that can accommodate the supercapacitor can be installed to any one of idle connectors of the server, thus there is no need to additionally arrange a space from the server for the supercapacitor. In other words, since the insertion part is universal for the connector standard, the supercapacitor carrier is ensured to fit different types of servers. In addition, the first side plates of the holder are able to secure the position of the supercapacitor in the accommodation space.

In some embodiments, the first side plates and the second side plates surround the supercapacitor so that the supercapacitor is prevented from moving in all directions when being held in the holder. And, the second side plates of curved shapes are able to press against the supercapacitor so as to eliminate the assembly tolerance between the supercapacitor and the second side plates and further secure the position of the supercapacitor in the accommodation space.

The embodiments are chosen and described in order to best explain the principles of the present disclosure and its practical applications, to thereby enable others skilled in the art best utilize the present disclosure and various embodiments with various modifications as are suited to the particular use being contemplated. It is intended that the scope of the present disclosure is defined by the following claims and their equivalents.

What is claimed is:

1. A supercapacitor carrier, configured to accommodate a supercapacitor and to be connected to a connector, and the supercapacitor carrier comprising:
a support component, comprising a substrate part and an insertion part, wherein the substrate part is connected to the insertion part, and the insertion part is configured to be inserted into the connector;
a holder, comprising a main plate and a first side plate, wherein the main plate and the substrate part are spaced apart from each other and form an accommodation space therebetween, the accommodation space is configured to accommodate the supercapacitor, the first side plate is connected to the main plate, and the first side plate is disposed on the substrate part; and
a baffle, disposed on the substrate part, wherein the baffle and the insertion part are located at different sides of the substrate part.

2. The supercapacitor carrier according to claim 1, wherein the substrate part further has a first surface and a second surface that are opposite to each other, the first side plate of the holder comprises a first blocking part and a first mount part, the first blocking part is connected to and located between the main plate and the first mount part, the first mount part is attached to and fixed to the first surface of the substrate part, the baffle comprises a second blocking part and a second mount part, the second blocking part is located at a side of the substrate part, the second mount part is connected to the second blocking part, and the second mount part is attached to and fixed to the second surface of the substrate part.

3. The supercapacitor carrier according to claim 1, wherein the holder further comprises a second side plate connected to the main plate, the second side plate and the first side plate are located at different sides of the main plate, the second side plate extends toward the substrate part, and the second side plate has a curved shape that is convex toward the accommodation space.

4. The supercapacitor carrier according to claim 1, wherein the main plate of the holder has an opening connected to the accommodation space.

5. The supercapacitor carrier according to claim 1, wherein the holder further comprises an elastic part connected to the main plate, and the elastic part extends toward the substrate part.

6. A server, comprising:
a chassis;
a circuit board, disposed on the chassis, wherein the circuit board has a connector;
a supercapacitor carrier, comprising:
a support component, comprising a substrate part and an insertion part, wherein the substrate part is connected to the insertion part, and the insertion part is inserted into the connector;
a holder, comprising a main plate and a first side plate, wherein the main plate and the substrate part are spaced apart from each other and form an accommodation space therebetween, the first side plate is connected to the main plate, and the first side plate is disposed on the substrate part; and
a baffle, disposed on the substrate part and the chassis, wherein the baffle and the insertion part are located at different sides of the substrate part; and
a supercapacitor, disposed in the accommodation space.

7. The server according to claim 6, wherein the substrate part further has a first surface and a second surface that are opposite to each other, the first side plate of the holder comprises a first blocking part and a first mount part, the first blocking part is connected to and located between the main plate and the first mount part, the first mount part is attached to and fixed to the first surface of the substrate part, the baffle comprises a second blocking part and a second mount part, the second blocking part is located at a side of the substrate part, the second mount part is connected to the second blocking part, and the second mount part is attached to and fixed to the second surface of the substrate part.

8. The server according to claim 6, wherein the holder further comprises a second side plate connected to the main plate, the second side plate and the first side plate are located at different sides of the main plate, the second side plate extends toward the substrate part, the second side plate has a curved shape that is convex toward the accommodation space, and the second side plate presses against the supercapacitor.

9. The server according to claim 6, wherein the main plate of the holder has an opening that is connected to the accommodation space and exposes the supercapacitor.

10. The server according to claim 6, wherein the holder further comprises an elastic part connected to the main plate, and the elastic part extends toward the substrate part and presses against the supercapacitor.
